(19) United States
(12) Patent Application Publication
(10) Pub. No.: US 2024/0170538 A1
(43) Pub. Date: May 23, 2024

(54) SEMICONDUCTOR STRUCTURE WITH STRAINED NANOSHEET CHANNEL

(71) Applicant: International Business Machines Corporation, Armonk, NY (US)

(72) Inventors: Liqiao Qin, Albany, NY (US); Heng WU, Santa Clara, CA (US); Ruilong Xie, Niskayuna, NY (US); Julien Frougier, Albany, NY (US); Min Gyu Sung, Latham, NY (US); Shogo Mochizuki, Mechanicville, NY (US); Andrew M. Greene, Slingerlands, NY (US)

(21) Appl. No.: 17/992,373

(22) Filed: Nov. 22, 2022

(51) Int. Cl. H01L 29/10; H01L 29/06; H01L 29/161

(52) U.S. Cl. CPC H01L 29/1054; H01L 29/0665; H01L 29/161

(57) ABSTRACT

A semiconductor structure includes a field-effect transistor region having a strained channel. The strained channel has a silicon germanium core layer and a silicon cladding layer disposed on the core layer.

### BACKGROUND

Known metal oxide semiconductor field-effect transistor (MOSFET) fabrication techniques include process flows for constructing planar field-effect transistors (FETs). A planar FET includes a substrate (also referred to as a silicon slab), a gate formed over the substrate; source and drain regions formed on opposite ends of the gate; and a channel region near the surface of the substrate under the gate. The channel region electrically connects the source region to the drain region while the gate controls the current in the channel. The gate voltage controls whether the path from drain to source is an open circuit (“off”) or a resistive path (“on”).

In recent years, research has been devoted to the development of nonplanar transistor architectures. For example, nanosheet FETs include a non-planar architecture that provides increased device density and some increased performance over lateral devices. In nanosheet FETs, in contrast to conventional planar FETs, the channel is implemented as a plurality of stacked and spaced apart nanosheets. The gate stack wraps around the full perimeter of each nanosheet, thus enabling fuller depletion in the channel region.

### SUMMARY

Illustrative embodiments of the present application include techniques for use in semiconductor manufacture. In one illustrative embodiment, a semiconductor structure comprises a field-effect transistor region comprising a strained channel. The strained channel comprises a silicon germanium core layer and a silicon cladding layer disposed on the silicon germanium core layer.

In another illustrative embodiment, a semiconductor structure comprises a nanosheet field-effect transistor region comprising a strained nanosheet channel comprising a plurality of nanosheet layers. Each nanosheet layer comprises a silicon germanium core layer comprising a middle portion having a first thickness and outer portions having a second thickness greater than the first thickness, and a silicon cladding layer disposed on the middle portion of the silicon germanium core layer.

In yet another illustrative embodiment, an integrated circuit comprises one or more semiconductor structures. At least one of the one or more semiconductor structures comprises a field-effect transistor region comprising a strained channel. The strained channel comprises a silicon germanium core layer and a silicon cladding layer disposed on the core layer.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a cross-sectional view illustrating a semiconductor structure at a first-intermediate fabrication stage, according to an illustrative embodiment.

FIG. 2 is a cross-sectional view illustrating a semiconductor structure at a second-intermediate fabrication stage, according to an illustrative embodiment.

FIG. 3 is a cross-sectional view illustrating a semiconductor structure at a third-intermediate fabrication stage, according to an illustrative embodiment.

FIG. 4 is a cross-sectional view illustrating a semiconductor structure at a fourth-intermediate fabrication stage, according to an illustrative embodiment.

FIG. 5 is a cross-sectional view illustrating a semiconductor structure at a fifth-intermediate fabrication stage, according to an illustrative embodiment.

FIG. 6 is a cross-sectional view of a semiconductor structure at a sixth-intermediate fabrication stage, according to an illustrative embodiment.

### DETAILED DESCRIPTION

Illustrative embodiments of the invention may be described herein in the context of illustrative methods for forming semiconductor structures with a nanosheet field-effect transistor (FET) having a strained nanosheet channel, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

As semiconductor devices continue to scale, stress engineering from external stressors becomes more challenging. Strain is a key factor to improve metal-oxide-semiconductor field-effect transistor (MOSFET) mobility. For example, strained silicon is a layer of silicon in which the silicon atoms are stretched beyond their normal interatomic distance. A strained channel can be utilized to more efficiently generate the channel strain necessary to achieve high mobility for carrier transport. However, it is a challenge to provide strain for an Si channel. Accordingly, non-limiting illustrative embodiments described herein overcome the above drawbacks discussed above, by utilizing a strained channel comprising a silicon germanium core layer and a silicon cladding layer disposed on the core layer.

It is to be understood that the various layers and/or regions shown in the accompanying drawings are not drawn to scale, and that one or more layers and/or regions of a type commonly used in, for example, field-effect transistor (FET), FinFET, VFET, CMOS, nanowire FET, nanosheet FETs, MOSFET, single electron transistor (SET) and/or other semiconductor devices may not be explicitly shown in a given drawing. This does not imply that the layers and/or regions not explicitly shown are omitted from the actual devices. In addition, certain elements may be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the terms “about” or “substantially” as used herein imply that a small margin of error may be present, such as 1% or less than the stated amount.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the figures. For example, as used herein, “vertical” refers to a direction perpendicular to the top surface of the substrate in the cross-sectional views, and “horizontal” refers to a direction parallel to the top surface of the substrate in the cross-sectional views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

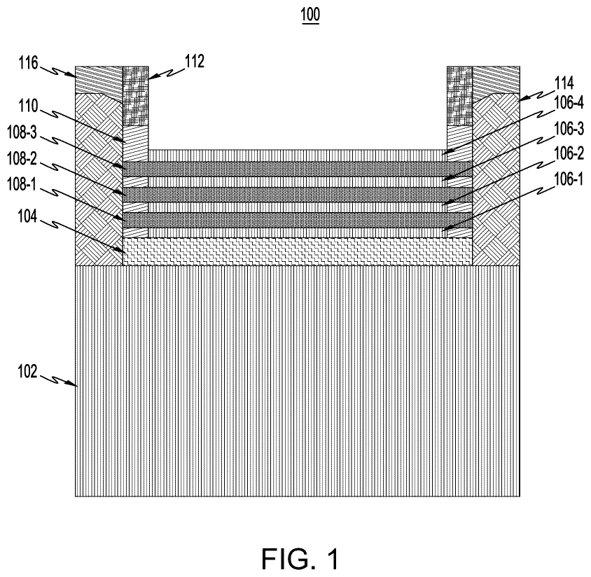

Referring now to the drawings in which like numerals represent the same of similar elements, FIGS. 1-6 illustrate various processes for fabricating semiconductor devices with a strained channel. With reference to FIGS. 1-6, these figures depict an example process for fabricating nanosheet transistors in accordance with one or more illustrative embodiments. In the particular embodiments illustrated, a single NFET is fabricated upon a substrate and/or wafer. It should be understood that in other embodiments, any combination of NFETs and PFETs or other combinations of any numbers of nanosheet semiconductor devices in addition to the particular nanosheet transistor of these illustrative embodiments, may be fabricated on a substrate in a similar manner.

Note that the same reference numeral (100) is used to denote the semiconductor structure through the various intermediate fabrication stages illustrated in FIGS. 1 through 6. Note also that the semiconductor structure described herein can also be considered to be a semiconductor device and/or an integrated circuit, or some part thereof. For the purpose of clarity, conventional techniques related to semiconductor device and strained channel fabrication may or may not be described in detail herein. Accordingly, some fabrication steps leading up to the production of the semiconductor structures as illustrated in FIGS. 1-6 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 is a cross-sectional view of semiconductor structure 100 at a first-intermediate fabrication stage. Semiconductor structure 100 is includes a substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

Dielectric layer 104 is formed over substrate 102. Dielectric layer 104 may be made of any known dielectric material such as, for example, silicon oxide, silicon nitride, hydrogenated silicon carbon oxide, low-k dielectrics, ultralow-k dielectrics, flowable oxides, porous dielectrics, or organic dielectrics including porous organic dielectrics. Low-k dielectric materials have a nominal dielectric constant less than the dielectric constant of SiO₂, which is approximately 4 (e.g., the dielectric constant for thermally grown silicon dioxide can range from 3.9 to 4.0). In one embodiment, low-k dielectric materials may have a dielectric constant of less than 3.7. Suitable low-k dielectric materials include, for example, fluorinated silicon glass (FSG), carbon doped oxide, a polymer, a SiCOH-containing low-k material, a non-porous low-k material, a porous low-k material, a spin-on dielectric (SOD) low-k material, or any other suitable low-k dielectric material. Ultra-low-k dielectric materials have a nominal dielectric constant less than 2.5. Suitable ultra-low-k dielectric materials include, for example, SiOCH, porous pSiCOH, pSiCNO, carbon rich silicon carbon nitride (C-Rich SiCN), porous silicon carbon nitride (pSiCN), boron and phosporous doped SiCOH/pSiCOH and the like.

The dielectric layer 104 may be formed by any suitable deposition technique known in the art, including atomic layer deposition (ALD), chemical vapor deposition (CVD), plasma enhanced chemical vapor deposition (PECVD), physical vapor deposition (PVD), molecular beam deposition (MBD), pulsed laser deposition (PLD), chemical solution deposition or other like processes. Subsequently, a planarization process such as a standard planarization process (e.g., a chemical mechanical planarization (CMP) process) can be carried out to planarize the upper surface of dielectric layer 104.

Nanosheets are initially formed over the substrate 102, where the nanosheets initially include nanosheet sacrificial layers 106-1, 106-2, 106-3 and 106-4 (collectively, nanosheet sacrificial layers 106) and channel sacrificial layers 108-1, 108-2 and 108-3 (collectively, channel sacrificial layers 108). The nanosheet sacrificial layers 106 may be formed of Si or another suitable material (e.g., a material similar to that used for the substrate 102).

The channel sacrificial layers 108 are formed of SiGe, but with designated percentage of Ge. For example, the channel sacrificial layers 108 may have a relatively lower percentage of Ge (e.g., 25% Ge). In illustrative embodiments, nanosheet sacrificial layers 106 can be SiGe_{y}% where the atomic percent % for “x” ranges from about 5 to about 25% atomic percent. The channel sacrificial layers 108 may each have a thickness in the range of about 5 to about 15 nanometers (nm).

Inner spacers 110 are formed to fill desired indent spaces (e.g., resulting from indent etches of the nanosheet sacrificial layers 106 prior to their removal). The inner spacers 110 may be formed of silicon nitride (SiN) or another suitable material such as SiBCN, silicon carbide oxide (SiCO), SiOCN, etc.

Semiconductor structure 100 further includes sidewall spacers 112 formed on inner spacers 110 and source/drain regions 114 discussed below. Suitable material for sidewall spacers 112 includes a nitride or an oxynitride such as, for example, Si₃N₄, SiBCN, SiNC, SiN, SiCO, SiO₂ and SiNOC. In some exemplary embodiments, sidewall spacers 112 can include a material that is resistant to some etching processes such as, for example, HF chemical etching or chemical oxide removal etching. The sidewall spacers 112 can be formed using conventional deposition techniques such as by PVD, ALD, CVD, etc.

The source/drain regions 114 may be formed using epitaxial growth processes. The source/drain regions 114 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

An interlayer dielectric (ILD) layer 116 is formed on source/drain regions 114, followed by planarization using chemical mechanical planarization (CMP) or any other suitable planarization process. The ILD layer 116 can be formed using conventional deposition techniques such as by PVD, ALD, CVD, etc. A suitable material for ILD layer 116 includes, for example, any suitable isolating material, such as SiO₂, SiOC, SiON, etc.

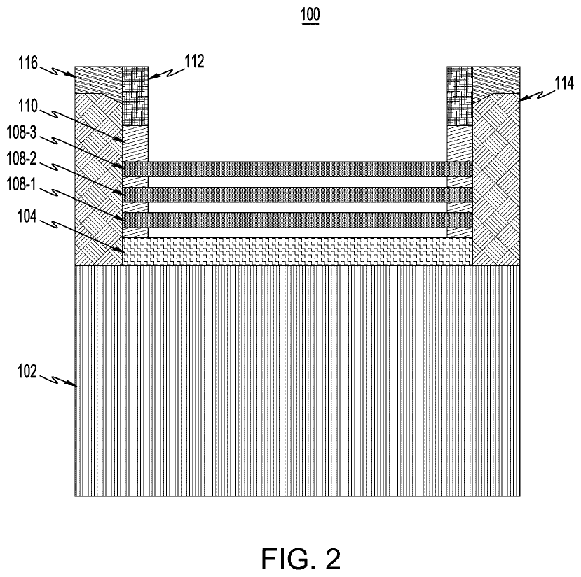

FIG. 2 is a cross-sectional view of the semiconductor structure 100 at a second-intermediate fabrication stage. During this stage, nanosheet sacrificial layers 106 are removed using a selective etching process such as a wet etch that is selective to the channel sacrificial layers 108 relative to the rest of semiconductor structure 100. The wet etch process can include, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. Following the removal of nanosheet sacrificial layers 106, the inner spacer 110 portions of channel sacrificial layers 108 are exposed.

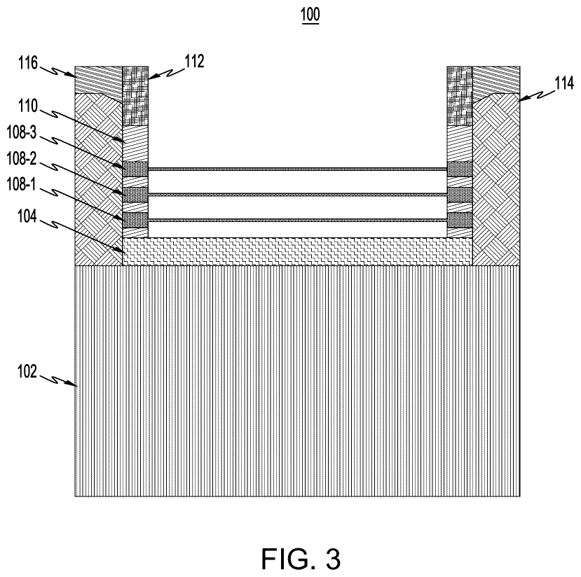

FIG. 3 is a cross-sectional view of the semiconductor structure 100 at a third-intermediate fabrication stage. During this stage, the exposed portions of channel sacrificial layers 108 are trimmed to a desired thickness between inner spacers 110. In an illustrative embodiment, the exposed portions of channel sacrificial layers 108 are trimmed using a suitable chemical etching process such as a vapor phase HCl etch. Following the trimming of exposed portions of channel sacrificial layers 108, the trimmed portions of channel sacrificial layers 108 may each have a thickness of less than 1 nm, e.g., a thickness ranging from about 0.5 nm to about 1 nm.

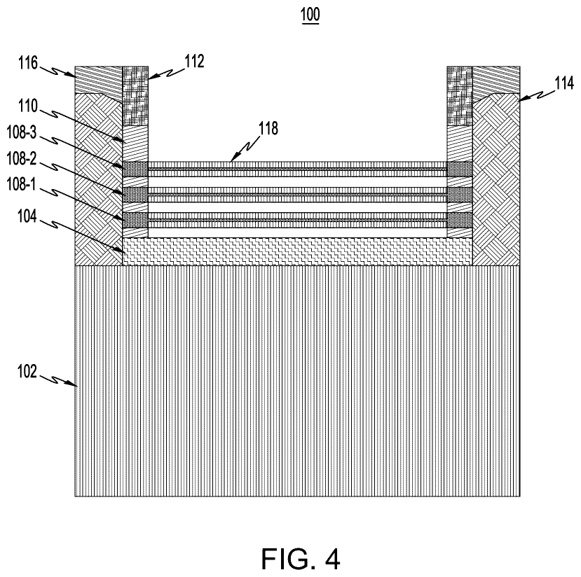

FIG. 4 is a cross-sectional view of the semiconductor structure 100 at a fourth-intermediate fabrication stage. During this stage, cladding layers 118 are formed on the trimmed portions of channel sacrificial layers 108. In illustrative embodiments, cladding layers 118 are formed from strained Si. For example, each of the cladding layers 118 will have stress due to mismatch with the trimmed portions of channel sacrificial layers 108. However, the combined layer of cladding layers 118 with the trimmed portions of channel sacrificial layers 108 as a whole has effectively zero stress. A layer of cladding layers 118 deposited on the trimmed portions of channel sacrificial layers 108 will thus be a strained layer such as a strained Si layer. In illustrative embodiments, cladding layers 118 are formed by growing a suitable cladding layer such as strained Si on the trimmed portions of channel sacrificial layers 108. The cladding layer 118 can be formed via a conventional epitaxial growth process.

Cladding layers 118 can have a thickness on each side of the trimmed portions of channel sacrificial layers 108 ranging from about 2 nm to about 7 nm or even larger, depending on the nanosheet stack design. In an illustrative embodiment, the thickness of the layer combined by cladding layers 118 and the trimmed portions of channel sacrificial layers 108 can be the same thickness as channel sacrificial layers 108 prior to the step of trimming, i.e., a thickness ranging from about 5 to about 15 nm.

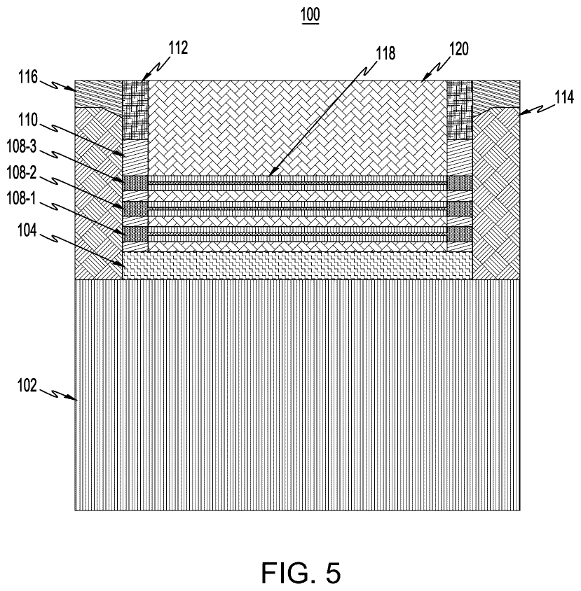

FIG. 5 is a cross-sectional view of the semiconductor structure 100 at a fifth-intermediate fabrication stage. During this stage, gate stack layer 120 is formed using, for example, replacement HKMG processing). The gate stack layer 120 may comprise a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg).

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

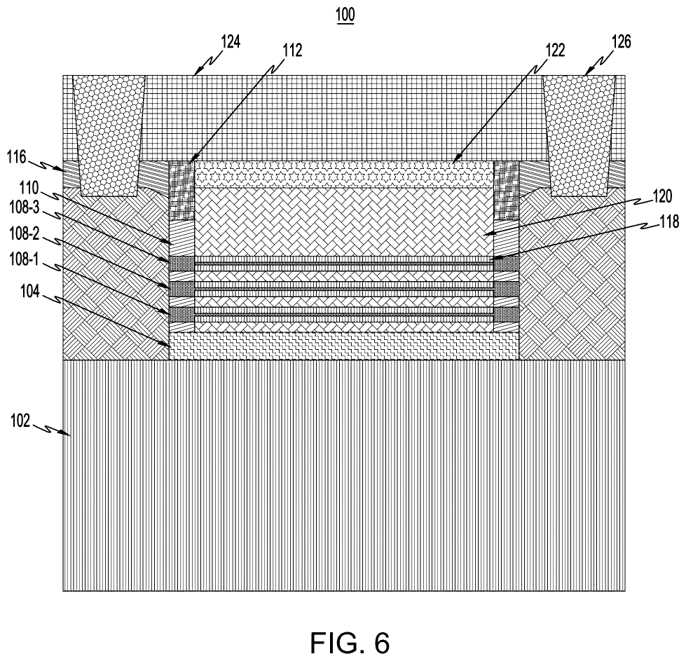

FIG. 6 is a cross-sectional view of the semiconductor structure 100 at a sixth-intermediate fabrication stage. During this stage, a gate cap layer 122 is deposited on the top surface of gate stack layer 120 after the gate stack layer 120 has been recessed to below a top surface of sidewall spacer 112. For example, gate cap layer 122 can be formed by depositing a layer of dielectric material (e.g., SiCO, SiC and SiN). Gate cap layer 122 is formed using a conventional deposition process including, for example, ALD, MLD, CVD, and PVD, among other known processes. In general, gate cap layer 122 can have a thickness ranging from about 10 nm to about 35 nm. In one embodiment, gate cap layer 122 can have a thickness ranging from about 10 nm to about 15 nm.

Next, ILD layer 124 is deposited on the top of semiconductor structure 100. ILD layer 124 can be formed by a similar process and of similar material as ILD layer 116. The material of the ILD layer 124 may initially be overfilled, followed by planarization (e.g., using CMP).

Middle-of-the-line contacts 126 are formed in ILD layer 124. For example, ILD layer 124 can be subjected to standard lithographic and etching processes to form middle-of-the-line contact openings. Middle-of-the-line contacts 126 are then formed by depositing a high conductance metal using any conventional technique such as ALD, CVD, PVD, and/or plating. Suitable contact metals include, a silicide liner such as Ti, Ni, or NiPt, etc, a thin adhesion metal liner, such as TiN, and high conductive metal fills, such as, for example, tungsten (W), aluminum (Al), copper (Cu), cobalt (Co), ruthenium (Ru), molybdenum (Mo), or any other suitable conductive material. The contact metals can be planarized using, for example, a planarizing process such as CMP. Other planarization processes can include grinding and polishing.

It is to be understood that the semiconductor devices and methods for forming same in accordance with embodiments described herein can be incorporated within semiconductor processing flows for fabricating other types of semiconductor structures and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with non-limiting illustrative embodiments can be employed in applications, hardware, and/or electronic systems.

Suitable hardware and systems for implementing the non-limiting illustrative embodiments may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the non-limiting illustrative embodiments provided herein, one of ordinary skill in the art will be able to contemplate other implementations and applications of the techniques described herein.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a field-effect transistor region comprising a strained channel;
wherein the strained channel comprises a silicon germanium core layer and a silicon cladding layer disposed on the silicon germanium core layer.

2. The semiconductor structure of claim 1, wherein the field-effect transistor region is an n-type field-effect transistor region.

3. The semiconductor structure of claim 1, wherein the silicon germanium core layer comprises a middle portion having a first thickness and outer portions having a second thickness greater than the first thickness.

4. The semiconductor structure of claim 3, wherein the silicon cladding layer is disposed on the middle portion.

5. The semiconductor structure of claim 3, wherein the first thickness is less than about 1 nanometer (nm).

6. The semiconductor structure of claim 5, wherein the second thickness is from about 5 nm to about 15 nm.

7. The semiconductor structure of claim 1, wherein the silicon germanium core layer comprises SiGeₓ% where the atomic percent % for x ranges from about 5 to about 25% atomic percent.

8. The semiconductor structure of claim 1, wherein the strained channel further comprises a gate structure.

9. A semiconductor structure, comprising:
a nanosheet field-effect transistor region comprising a strained nanosheet channel comprising a plurality of nanosheet layers;
wherein each nanosheet layer comprises a silicon germanium core layer comprising a middle portion having a first thickness and outer portions having a second thickness greater than the first thickness, and a silicon cladding layer disposed on the middle portion of the silicon germanium core layer.

10. The semiconductor structure of claim 9, wherein the nanosheet field-effect transistor region is an n-type nanosheet field-effect transistor region.

11. The semiconductor structure of claim 9, wherein a top surface of the silicon cladding layer is aligned with a top surface of the outer portions of the silicon germanium core layer.

12. The semiconductor structure of claim 9, wherein the first thickness is less than about 1 nm.

13. The semiconductor structure of claim 12, wherein the second thickness is from about 5 nm to about 15 nm.

14. The semiconductor structure of claim 9, wherein the strained nanosheet channel further comprises inner spacers disposed on a sidewall of the outer portions of the silicon germanium core layer.

15. The semiconductor structure of claim 10, wherein the n-type nanosheet field-effect transistor region further comprises a source/drain region and a gate structure.

16. An integrated circuit, comprising:
one or more semiconductor structures, wherein at least one of the one or more semiconductor structures comprises:
a field-effect transistor region comprising a strained channel;
wherein the strained channel comprises a silicon germanium core layer and a silicon cladding layer disposed on the silicon germanium core layer.

17. The integrated circuit of claim 16, wherein the silicon germanium core layer comprises a middle portion having a first thickness and outer portions having a second thickness greater than the first thickness.

18. The integrated circuit of claim 17, wherein the silicon cladding layer is disposed on the middle portion.

19. The integrated circuit of claim 16, wherein the field-effect transistor region is an n-type field-effect transistor region.

20. The integrated circuit of claim 16, wherein the silicon germanium core layer comprises SiGeₓ% where the atomic percent % for x ranges from about 5 to about 25% atomic percent.
